(19) United States
(12) Patent Application Publication
(10) Pub. No.: US 2025/0259973 A1
(43) Pub. Date: Aug. 14, 2025

(54) ELECTRONIC PACKAGE DEVICE

(71) Applicant: SAMSUNG ELECTRONICS CO., LTD., Suwon-si (KR)

(72) Inventors: Jiheon OH, Suwon-si (KR); Dohun Kim, Suwon-si (KR); Jiho You, Suwon-si (KR); Seungwoo Lee, Suwon-si (KR); Wooseok Jang, Suwon-si (KR); Kyuchae Cho, Suwon-si (KR); Yonggi Cho, Suwon-si (KR)

(73) Assignee: SAMSUNG ELECTRONICS CO., LTD., Suwon-si (KR)

(21) Appl. No.: 18/808,445

(22) Filed: Aug. 19, 2024

(30) Foreign Application Priority Data
Feb. 8, 2024 (KR) 10-2024-0019832

(51) Int. Cl. H01L 25/075; H01L 33/50; H01L 33/62

(52) U.S. Cl. CPC H01L 25/0753; H10H 20/857; H10H 20/851

(57) ABSTRACT

Provided is an electronic package device including a package substrate including a flat plate and a pad on the flat plate, wherein a width of the flat plate in a first horizontal direction is greater than a width of the pad in the first horizontal direction, and a light-emitting device on the package substrate, wherein the pad includes a first portion, and a second portion positioned on a top surface of the first portion and positioned at an edge of the top surface of the first portion, and a width of the light-emitting device in the first horizontal direction is substantially equal to a width of the pad in the first horizontal direction.

### CROSS-REFERENCE TO RELATED APPLICATION

This application is based on and claims priority under 35 U.S.C. § 119 to Korean Patent Application No. 10-2024-0019832, filed on Feb. 8, 2024, in the Korean Intellectual Property Office, the disclosure of which is incorporated by reference herein in its entirety.

### BACKGROUND

Embodiments of the present disclosure relate to an electronic package device, and more particularly, to a headlamp driving device.

In general, vehicles are equipped with various vehicular lamps that have a lighting function and a signaling function. The lighting function may aid in identifying objects located around the vehicle when driving at night and the signaling function may inform other vehicles or road users of the vehicle's driving status.

Among lamps mounted on vehicles, a headlamp which secures the driver's forward vision when driving at night generally has a function of simultaneously or separately emitting a low beam (low beam), which illuminates a short distance in front of the vehicle, and a high beam (upward beam), which illuminates a long distance in front of the vehicle.

From the driver's perspective, using both low beams and high beams simultaneously is ideal for visibility because it can secure the driver's view of near and far distances in front of the vehicle at the same time. However, the high beam poses the risk of dazzling drivers of oncoming vehicles or oncoming pedestrians, making them unable to secure their vision during the time required for light and dark adaptation.

In addition, the driver's repeated on/off operation of the high beam while continuously checking for oncoming vehicles or pedestrians also undermines the safety of vehicle operation and causes the driver to feel considerable discomfort.

To address these issues, driver assistance systems are being developed, such as automatically controlling high beam on/off depending on the presence or absence of oncoming and/or preceding vehicles or controlling the illumination angle and/or brightness of low beam/high beam depending on road conditions, such as city streets, highways, intersections, etc.

Recently, adaptive driving beam (ADB) technology has been evolved to detect oncoming vehicles, preceding vehicles, and pedestrians using video images from the front of the vehicle. The ADB technology may change the lamp angle or turns off the high bean in a specific area where vehicles, pedestrians, and the like are located to prevent dazzling detected road users.

### SUMMARY

One or more example embodiments provide an electronic package device with reduced internal stress by reducing the deviation of the vertical thickness of the solder paste that attaches the package substrate to the light-emitting device.

According to an aspect of the present disclosure, an electronic package device may include: a package substrate including a flat plate and a pad on the flat plate, wherein a width of the flat plate in a first horizontal direction is greater than a width of the pad in the first horizontal direction; and a light-emitting device on the package substrate, wherein the pad may include: a first portion; and a second portion positioned on a top surface of the first portion and positioned at an edge of the top surface of the first portion, and a width of the light-emitting device in the first horizontal direction is substantially equal to a width of the pad in the first horizontal direction.

According to another aspect of the present disclosure, an electronic package device may include: a package substrate including a flat plate and a pad on the flat plate, wherein a width of the flat plate in a first horizontal direction is greater than a width of the pad in the first horizontal direction; and a light-emitting device on the package substrate, wherein the light-emitting device may include a base, a plurality of phosphors disposed on the base and spaced apart from each other in the first horizontal direction, and a grid surrounding sidewalls of the plurality of phosphors; and solder paste positioned between the light-emitting device and the pad, wherein the pad may include a first portion and a second portion disposed on a top surface of the first portion and arranged in a ring shape or an annular shape along an edge of the top surface of the first portion, the solder paste fills a space defined by the top surface of the first portion and inner walls of the second portion, and the plurality of phosphors are included in the solder paste from a plan view.

According to another aspect of the present disclosure, an electronic package device may include: a package substrate including a flat plate and a pad on the flat plate, wherein a width of the flat plate in a first horizontal direction is greater than a width of the pad in the first horizontal direction; a light-emitting device on the package substrate, wherein the light-emitting device may include a base, a plurality of phosphors disposed on the base and spaced apart from each other in the first horizontal direction, a grid surrounding sidewalls of the plurality of phosphors, and an input/output pad disposed on an upper part of the base; solder paste positioned between the light-emitting device and the pad; prepreg on a top surface of the flat plate, wherein the prepreg surrounds sides of the pad; a connection wire disposed within the prepreg; a connecting member that directly connects the connection wire to the input/output pad; and a molding member covering the connecting member, wherein the pad may include a first portion and a second portion positioned on a top surface of the first portion and positioned at an edge of the top surface of the first portion, the solder paste fills a space defined by the top surface of the first portion and inner walls of the second portion, and a top surface of the second portion is in direct contact with a bottom surface of the light-emitting device.

According to another aspect of the present disclosure, an electronic device may include: a printed circuit board including a pedestal structure, wherein the pedestal structure may include: a recess that contains solder paste; and shoulders of the recess; and a light emitting device disposed on the solder paste and the shoulders of the pedestal structure.

### BRIEF DESCRIPTION OF DRAWINGS

The above and/or other aspects will be more apparent by describing certain example embodiments, with reference to the accompanying drawings, in which:

FIG. 1 is a plan view of an electronic package device according to an embodiment;

FIG. 2A is a cross-sectional view taken along line A-A′ in FIG. 1;

FIG. 2B is a cross-sectional view taken along line B-B′ in FIG. 1;

FIG. 3A is a cross-sectional view taken along line A-A′ in FIG. 1;

FIG. 3B is a cross-sectional view taken along line B-B′ in FIG. 1;

FIG. 4 is a cross-sectional view taken along line A-A′ in FIG. 1;

FIG. 5A is a cross-sectional view taken along line A-A′ in FIG. 1;

FIG. 5B is a cross-sectional view taken along line B-B′ in FIG. 1;

FIG. 6 is a plan view of an electronic package device according to an embodiment;

FIG. 7A is a cross-sectional view taken along line C-C′ in FIG. 6;

FIG. 7B is a cross-sectional view taken along line D-D′ in FIG. 6;

FIG. 8 is a plan view of an electronic package device according to an embodiment;

FIG. 9A is a cross-sectional view taken along line E-E′ in FIG. 8;

FIG. 9B is a cross-sectional view taken along line F-F′ in FIG. 8;

FIGS. 10, 12, 14, and 16 are plan views illustrating a method of manufacturing an electronic package device according to an embodiment;

FIGS. 11A, 13A, 15A, and 17A are cross-sectional views, taken along line A-A′ in FIGS. 10, 12, 14, and 16, respectively, illustrating a method of manufacturing an electronic package device according to an embodiment;

FIGS. 11B, 13B, 15B, and 17B are cross-sectional views, taken along line B-B′ in FIGS. 10, 12, 14, and 16, respectively, illustrating a method of manufacturing an electronic package device according to an embodiment;

FIG. 18 is a block diagram of a headlamp control system according to an embodiment; and

FIG. 19 is a diagram showing a vehicle including the headlamp control system of FIG. 18.

### DETAILED DESCRIPTION OF EMBODIMENTS

Hereinafter, various embodiments are described with reference to the accompanying drawings.

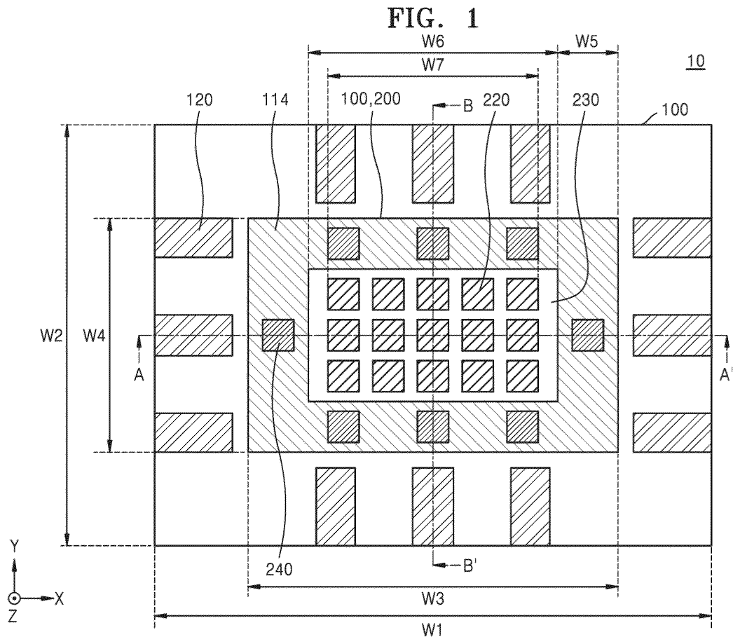

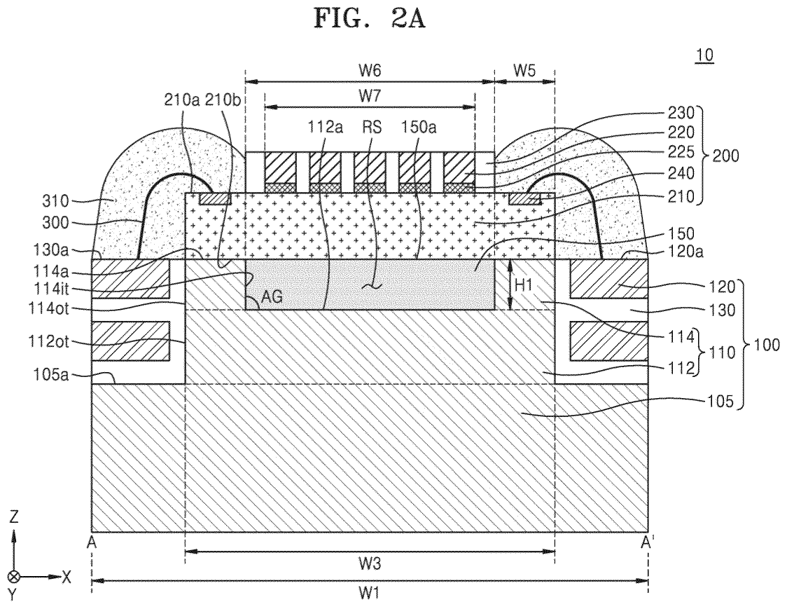

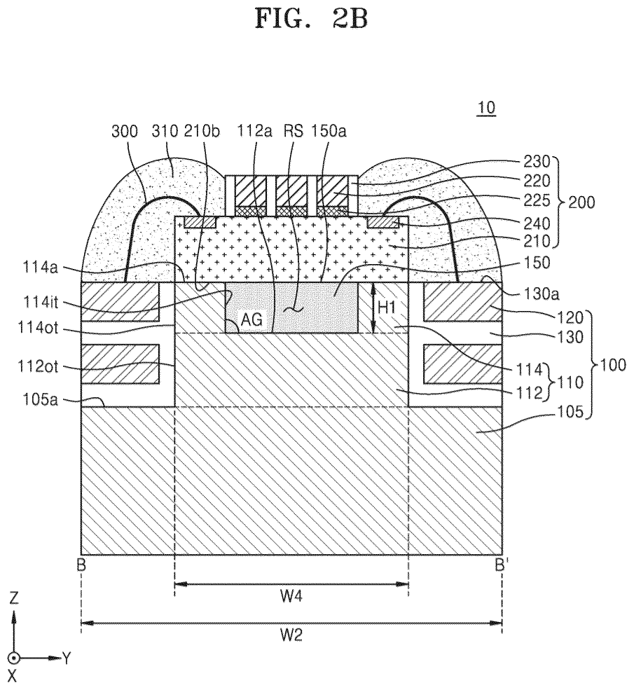

FIG. 1 is a plan view of an electronic package device according to an embodiment. FIG. 2A is a cross-sectional view taken along line A-A′ in FIG. 1. FIG. 2B is a cross-sectional view taken along line B-B′ in FIG. 1.

Referring to FIGS. 1, 2A, and 2B, an electronic package device 10 may include a package substrate 100, solder paste 150, a light-emitting device 200, a connecting member (e.g., a wire) 300, and a molding member 310.

The electronic package device 10 may include, for example, a headlamp driving device. The headlamp driving device may include a lamp mounted on a vehicle. A headlamp may be a lamp for securing a driver's forward vision when driving at night.

The electronic package device 10 may be a semiconductor package although its implementation is not limited to a semiconductor package.

The package substrate 100 may include, for example, a printed circuit board (PCB). Alternatively, the package substrate 100 may include a base plate made of a metal material, such as copper. As an example, the package substrate 100 may include conductive wires within a flat plate 105 and a pad 110. The conductive wires may be electrically connected to a light-emitting device driving circuit placed externally or the light-emitting device 200 mounted on the package substrate 100 through connection wires 120.

The package substrate 100 may include the flat plate 105, the pad 110, the connection wires 120, and a prepreg 130.

The flat plate 105 may extend along two perpendicular horizontal directions: a first horizontal direction (X) and a second horizontal direction (Y). The length of the flat plate 105 in the first horizontal direction (X) may be a first width W1. The length of the flat plate 105 in the second horizontal direction (Y) may be a second width W2. The first width W1 may be greater than the second width W2.

In an embodiment, the flat plate 105 may have a rectangular planar shape. However, embodiments of the present disclosure are not limited thereto, and a planar shape of the flat plate 105 may vary, such as square, polygon, and circle.

Herein, the first horizontal direction (X) is defined as a direction parallel to a top surface 105a of the flat plate 105, the second horizontal direction (Y) is defined as a direction parallel to the top surface 105a of the flat plate 105 and intersecting the first horizontal direction (X), and a vertical direction (Z) is defined as a direction perpendicular to the top surface 105a of the flat plate 105.

The pad 110 may be disposed on the flat plate 105. The pad 110 may be integrated with the flat plate 105. That is, there may be no boundary between the pad 110 and the flat plate 105. However, in another embodiment, the pad 110 and the flat plate 105 may be formed separately and then attached to each other, resulting in a visible boundary between the pad 110 and the flat plate 105. The flat plate 105 and the pad 110 may be collectively referred to as a pedestal structure that is used to elevate and support specific components (e.g., a light-emitting device 200), ensuring the components are properly positioned and secured on the PCB. The pedestal structure, also referred to as a raised support structure, may include a recess RS to contain solder paste 150. A first portion 112 of the pad 10 may be positioned under the recess RS, and shoulders of the recess RS may correspond to the second portion 114 of the pad 10.

The length of the pad 110 in the first horizontal direction (X) may be a third width W3. The length of the pad 110 in the second horizontal direction (Y) may be a fourth width W4. The third width W3 may be less than the first width W1. The third width W3 may be greater than the fourth width W4. The fourth width W4 may be less than the second width W2.

The pad 110 may include a first portion 112 and a second portion 114 on the first portion 112.

The first portion 112 may be placed directly above the flat plate 105. As an example, the first portion 112 may be integrated with the flat plate 105.

The first portion 112 may extend in the first horizontal direction (X) and the second horizontal direction (Y). The length of the first portion 112 in the first horizontal direction (X) may be equal to the third width W3. The length of the first portion 112 in the second horizontal direction (Y) may be equal to the fourth width W4.

The second portion 114 may be placed on the first portion 112. From a cross-sectional view, the second portion 114 may be placed at an edge of a top surface 112a of the first portion 112. From a plan view, the second portion 114 may have a ring shape or an annular shape. In other words, the second portion 114 may be placed along the edge of the first portion 112. In an embodiment, the second portion 114 may have a rectangular planar shape. However, embodiments of the present disclosure are not limited thereto, and the planar shape of the second portion 114 may vary, such as square, polygon, and circle.

Since the second portion 114 has a ring shape or an annular planar shape, at least a part of the top surface 112a of the first portion 112 may be exposed from the second portion 114. Additionally, because the second portion 114 has a ring shape or an annular planar shape, the pad 110 may include a recess RS.

The recess RS may be a space defined by the top surface 112a of the first portion 112 and a plurality of inner walls 114it of the second portion 114. Due to the recess RS, the vertical level of the top surface 112a of the first portion 112 may be lower than the vertical level of the top surface 114a of the second portion 114.

The horizontal width of the second portion 114 may be a fifth width W5. The fifth width W5 may be the minimum distance from an outer wall 114ot to the inner wall 114it of the second portion 114. In FIGS. 1 and 2A, the fifth width W5 is shown as a distance in the first horizontal direction (X), but the fifth width W5 may also be a distance in the second horizontal direction (Y).

The fifth width W5 may be less than half of the fourth width W4. The fifth width W5 may be greater than or equal to 50 μm

The vertical height of the second portion 114 may be a first height H1. The first height H1 may be a vertical distance from the top surface 112a of the first portion 112 to the top surface 114a of the second portion 114. The first height H1 may be in a range from about 10 μm to about 500 μm.

An angle AG formed between the inner wall 114it of the second portion 114 and the top surface 112a of the first portion 112 may be a right angle or an obtuse angle. Specifically, the angle AG formed between the inner wall 114it of the second portion 114 and the top surface 112a of the first portion 112 may be about 90 degrees to about 145 degrees.

An outer wall 112ot of the first portion 112 and the outer wall 114ot of the second portion 114 may be placed on a straight line.

The solder paste 150 may fill the recess RS. The solder paste 150 may directly cover the top surface 112a of the first portion 112 and the inner walls 114it of the second

The vertical level of a top surface 150a of the solder paste 150 may be substantially equal to the vertical level of the top surface 114a of the second portion 114. Herein, the term “substantially equal” may include mathematical identity as well as a margin of error in the process, ranging from-50 μm to 50 μm.

The solder paste 150 may fill the space surrounded by the top surface 112a of the first portion 112 and the inner walls 114it of the second portion 114. That is, the solder paste 150 may fill the recess RS. From a plan view, the solder paste 150 may be surrounded by the second portion 114.

The solder paste 150 may include a solder material. For example, the solder paste 150 may include a mixture of metals, such as lead, arsenic, platinum, indium, and platinum, and resin. The solder paste 150 may further include flux.

The connection wires 120 and the prepreg 130 may be disposed on the top surface 105a of the flat plate 105 of the package substrate 100. From a plan view, the prepreg 130 may surround the pad 110 of the package substrate 100. The prepreg 130 may directly cover the outer wall 112ot of the first portion 112 and the outer wall 114ot of the second portion 114.

The connection wires 120 may be placed within the prepreg 130. The connection wires 120 may include one or two or more layers. The prepreg 130 may not cover the top surface 120a of the uppermost connection wire 120.

The light-emitting device 200 may be disposed on the top surface 114a of the second portion 114 of the package substrate 100. The light-emitting device 200 may be disposed on the top surface 150a of the solder paste 150.

The light-emitting device 200 may have a structure in which light is emitted from a plurality of light-emitting structures arranged in a pixel type. For example, the light-emitting device 200 may be arranged in a pixel type to be used in an intelligent lighting system, such as a car headlamp or indoor lighting.

The light-emitting device 200 may include a base 210, a phosphor 220, a light-emitting diode 225, a grid 230, and an input/output pad 240.

A bottom surface 210b of the base 210 may directly contact the top surface 114a of the second portion 114 and the top surface 150a of the solder paste 150. The bottom surface 210b of the base 210 may also be referred to as a bottom surface of the light-emitting device 200. Accordingly, the bottom surface of the light-emitting device 200 may directly contact the top surface 114a of the second portion 114 and the top surface 150a of the solder paste 150. The bottom surface 210b of the base 210 may be spaced apart from the first portion 112 in the vertical direction (Z).

In some embodiments, the base 210 may include a silicon interposer and a wiring layer disposed on the silicon interposer. The wiring layer may be electrically connected to the light-emitting diode 225 and the input/output pad 240.

In some embodiments, the width of the light-emitting device 200 in the first horizontal direction (X) may be equal to the width of the base 210 in the first horizontal direction (X). The width of the light-emitting device 200 in the second horizontal direction (Y) may be equal to the width of the base 210 in the second horizontal direction (Y). The width of the light-emitting device 200 in the first horizontal direction (X) may be greater than the width of the light-emitting device 200 in the second horizontal direction (Y). The width of the light-emitting device 200 in the second horizontal direction (Y) may be about 2 mm to about 6 mm.

The width of the light-emitting device 200 in the first horizontal direction (X) may be substantially equal to the third width W3. The width of the light-emitting device 200 in the second horizontal direction (Y) may be substantially equal to the fourth width W4. Specifically, the width of the light-emitting device 200 in the first horizontal direction (X) may be substantially equal to the width of the pad 110 in the first horizontal direction (X). The width of the light-emitting device 200 in the second horizontal direction (Y) may be substantially equal to the width of the pad 110 in the second horizontal direction (Y).

The light-emitting diode 225 and the phosphor 220 may be disposed on a top surface 210a of the base 210. The light-emitting diode 225 and the phosphor 220 may be sequentially stacked on the top surface 210a of the base 210.

The number of light-emitting diodes 225 and the number of phosphors 220 may be plural. The plurality of light-emitting diodes 225 may be spaced apart from each other in the first horizontal direction (X) and the second horizontal direction (Y). The plurality of light-emitting diodes 225 may be arranged in a certain arrangement in the first horizontal direction (X) and the second horizontal direction (Y).

The plurality of phosphors 220 may be spaced apart from each other in the first horizontal direction (X) and the second horizontal direction (Y). The plurality of phosphors 220 may be arranged in a certain arrangement in the first horizontal direction (X) and the second horizontal direction (Y).

The grid 230 may surround the plurality of light-emitting diodes 225 and the plurality of phosphors 220. The grid 230 may be placed between a pair of adjacent phosphors 220 in the first horizontal direction (X) or the second horizontal direction (Y). The grid 230 may be placed between a pair of adjacent light-emitting diodes 225 in the first horizontal direction (X) or the second horizontal direction (Y).

From a plan view, the grid 230 may have a mesh shape. The plurality of light-emitting diodes 225 may be spaced apart from each other in the first horizontal direction (X) and the second horizontal direction (Y), with the grid 230 positioned in between. The plurality of phosphors 220 may be spaced apart from each other in the first horizontal direction (X) and the second horizontal direction (Y), with the grid 230 positioned in between.

The phosphor 220 may include an inorganic receptor material including an optically active dopant. For example, the phosphor 220 may include yttrium aluminum garnet Y₃Al₅O₁₂ (YAG). The optically active dopant may include rare earth oxides or rare earth compounds.

The phosphor 220, the light-emitting diode 225, and the grid 230 may be collectively referred to as a pixel light-emitting structure. The pixel light-emitting structure may be configured to emit light upward from the top surface of the phosphor 220, for example, to the outside of the electronic package device 10.

The distance between the inner walls 114it of the pair of second portions 114 facing each other in the first horizontal direction (X) may be a sixth width W6. The sixth width W6 may be equal to the width of the solder paste 150 in the first horizontal direction (X). The distance between the outermost ones of the plurality of phosphors 220 arranged in the first horizontal direction (X) may be a seventh width W7. The seventh width W7 may be less than or equal to the sixth width W6. That is, from a plan view, all of the plurality of phosphors 220 may be placed within the solder paste 150. From a plan view, the plurality of light-emitting diodes 225 may all be placed within the solder paste 150. The plurality of phosphors 220 and the plurality of light-emitting diodes 225 may vertically overlap with the solder paste 150.

According to an embodiment, the plurality of phosphors 220 may all be placed within the solder paste 150 from a plan view. Thus, heat generated from the plurality of phosphors 220 may be easily discharged to the package substrate 100 through the solder paste 150. As a result, the thermal properties of the electronic package device 10 may be improved.

The width of the base 210 in the first horizontal direction (X) may be less than or equal to the third width W3. The width of the base 210 in the first horizontal direction (X) may be greater than the sixth width W6.

The input/output pad 240 may be placed on an upper part of the base 210. The top surface of the input/output pad 240 may be exposed from the base 210. The input/output pad 240 may include a conductive metal, such as copper or aluminum.

The connecting member 300 may be arranged to connect the input/output pad 240 to the uppermost connection wire 120. The connecting member 300 may directly connect the input/output pad 240 to the uppermost connection wire 120. The connecting member 300 may electrically connect the input/output pad 240 to the uppermost connection wire 120. The connecting member 300 may be formed by wire bonding.

The connecting member 300 may include a metal. For example, the connecting member 300 may include a low-resistance metal, such as gold, platinum, copper, or aluminum.

The molding member 310 covering the connecting member 300 may be placed on the light-emitting device 200. The molding member 310 may cover the prepreg 130 and the uppermost connection wire 120. The molding member 310 may cover the top surface 210a and a portion of the side surface of the base 210. The molding member 310 may cover at least a portion of the side surface of the grid 230.

When the pad 110 includes only the first portion 112 and omits the second portion 114, the solder paste 150 may be disposed on the top surface 112a of the first portion 112. In the process of forming the solder paste 150, the solder paste 150 may retain fluidity. Therefore, in the absence of a structure to fix or secure the solder paste 150, the vertical thickness of the solder paste 150 may vary gradually in the first horizontal direction (X) or the second horizontal direction (Y). This variation may lead to deviations in the vertical thickness of the solder paste 150 in the first horizontal direction (X) and/or the second horizontal direction (Y).

In a region that vertically overlaps with a portion of the solder paste 150 with a small vertical thickness, there may be increased stress on the light-emitting device 200. On the other hand, in a region that vertically overlaps with another portion of the solder paste 150 with a large vertical thickness, increased stress may be observed on the connecting member 300. Thus, variations in the vertical thickness of the solder paste 150 may lead to increased stress in the electronic package device 10.

In the electronic package device 10 according to an embodiment, the pad 110 of the package substrate 100 may include the first portion 112 and the second portion 114 on the first portion 112. The second portion 114 may have a ring shape or an annular shape in a plan view. In other words, the second portion 114 may be placed along the edge of the first portion 112. As a result, the pad 110 may include the recess RS. The recess RS may be a space defined by the top surface 112a of the first portion 112 and the inner walls 114it of the second portion 114. Additionally, the solder paste 150 may fill the recess RS. In this case, during the process of forming the solder paste 150, the solder paste 150 may be fixed by the second portion 114. As a result, the deviation in the vertical thickness of the solder paste 150 may decrease. Accordingly, stress occurring inside the electronic package device 10 may be reduced. For the above reasons, the reliability of the electronic package device 10 may be improved.

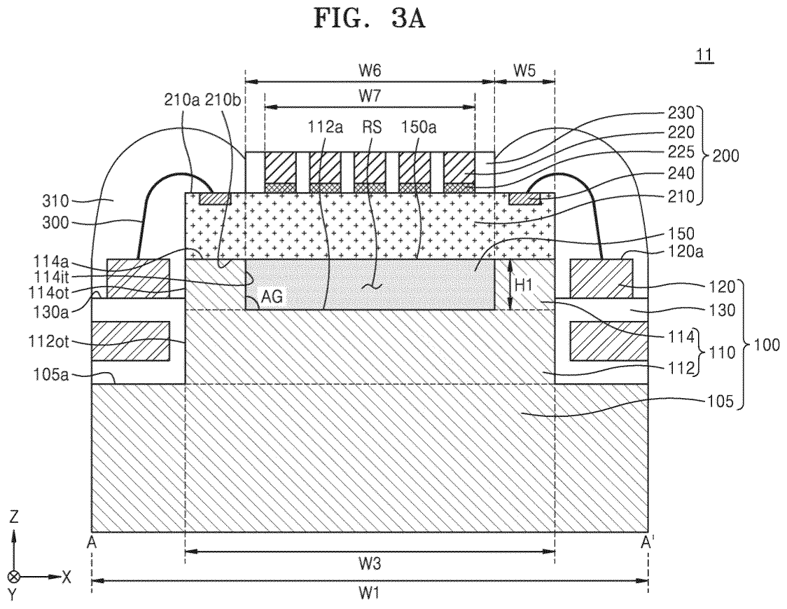

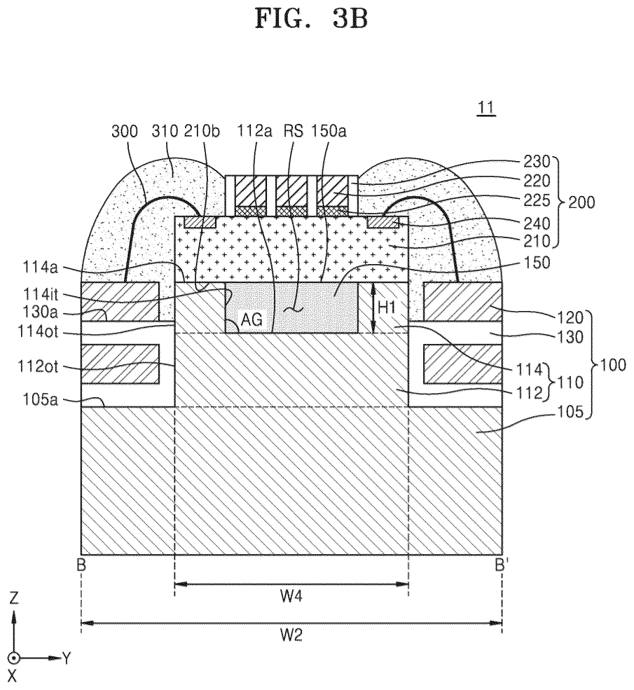

FIG. 3A is a cross-sectional view taken along line A-A′ in FIG. 1. FIG. 3B is a cross-sectional view taken along line B-B′ in FIG. 1. Hereinafter, descriptions that are substantially the same as those given with reference to FIGS. 1 to 2B are omitted, and only the differences are described in detail.

Referring to FIGS. 1, 3A, and 3B, the vertical level of a top surface of a prepreg 130 of an electronic package device 11 may be lower than the vertical level of the top surface 114a of the second portion 114 of the pad 110. The prepreg 130 may cover at least a portion of the outer wall 114ot of the second portion 114. Alternatively, unlike in FIGS. 3A and 3B, the prepreg 130 may not cover the outer wall 114ot of the second portion 114.

The prepreg 130 may not cover the top surface 120a and side surfaces of the uppermost connection wire 120. The uppermost connection wire 120 may be disposed on the top surface 130a of the prepreg 130. The molding member 310 may cover the top surface 120a and the side surfaces of the uppermost connection wire 120. The bottom surface of the uppermost connection wire 120 may contact the top surface 130a of the prepreg 130.

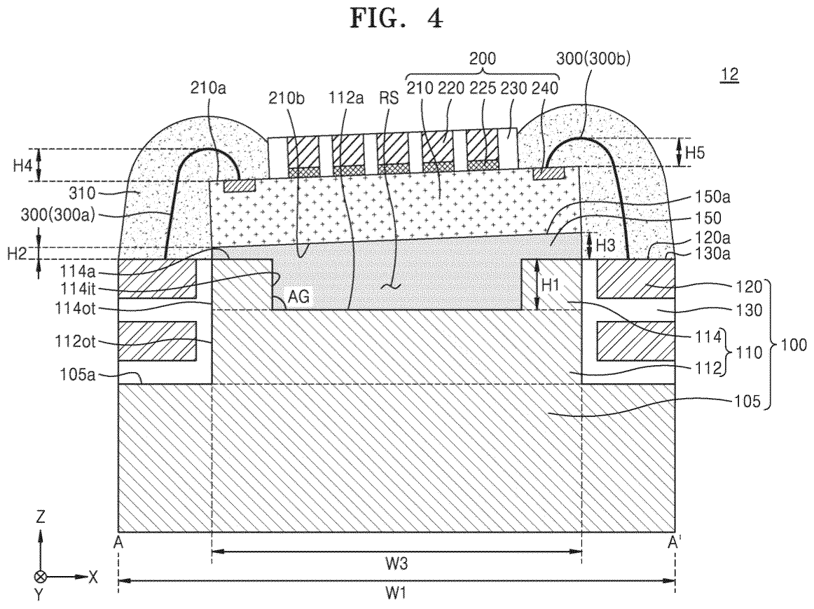

FIG. 4 is a cross-sectional view taken along line A-A′ in FIG. 1. Hereinafter, descriptions that are substantially the same as those given with reference to FIGS. 1 to 2B are omitted to focus on differences in detail. The cross-sectional view taken along line B-B′ in FIG. 1 may correspond to FIG. 2B.

Referring to FIGS. 1, 2B, and 4, the vertical level of a top surface 150a of a solder paste 150 of an electronic package device 12 may be higher than the vertical level of the top surface 114a of the second portion 114 of the pad 110. The vertical level of the top surface 150a of the solder paste 150 may increase in the first horizontal direction (X). That is, the top surface 150a of the solder paste 150 may be inclined at a certain angle with the first horizontal direction (X).

The minimum vertical distance from the top surface 114a of the second portion 114 to the top surface 150a of the solder paste 150 may be a second height H2. The maximum vertical distance from the top surface 114a of the second portion 114 to the top surface 150a of the solder paste 150 may be a third height H3. The third height H3 may be greater than the second height H2. The third height H3 may be greater than 0 and about 80 μm or less. The difference between the third height H3 and the second height H2 may be less than or equal to 30 μm.

The light-emitting device 200 may be spaced apart from the second portion 114 in the vertical direction (Z) with the solder paste 150 positioned in between. The entirety of the bottom surface 210b of the base 210 of the light-emitting device 200 may be in contact with the top surface 150a of the solder paste 150.

The thermal expansion coefficient of the base 210 of the light-emitting device 200 may be different from the thermal expansion coefficient of the second portion 114. When the second portion 114 of the pad 110 of the package substrate 100 is not present, the difference between the third height H3 and the second height H2 may increase. In this case, in a region where the vertical thickness of the solder paste 150 is small, the stress occurring inside the light-emitting device 200 and the solder paste 150 may increase. This may result in deterioration of the reliability of the electronic package device 12.

According to an embodiment, the second portion 114 of the pad 110 may secure the solder paste 150 pad. Accordingly, the tilt of the top surface 150a of the solder paste 150 may be reduced. Specifically, the difference between the third height H3 (i.e., the maximum vertical distance from the top surface 114a of the second portion 114 to the top surface 150a of the solder paste 150) and the second height H2 (i.e., the minimum vertical distance from the top surface 114a of the second portion 114 to the top surface 150a of the solder paste 150) may be maintained to be less than or equal to 30 μm. That is, the difference between the third height H3 and the second height H2 may be reduced. When the difference between the third height H3 and the second height H2 is less than or equal to 30 μm, stress occurring inside the light-emitting device 200 and the package substrate 100 may be greatly reduced. For the above reasons, the reliability of the electronic package device 12 may be improved.

The connecting member 300 adjacent to a portion of the solder paste 150 having the second height H2 may include a first connecting member 300a. The connecting member 300 adjacent to another portion of the solder paste 150 having the third height H3 may include a second connecting member 300b. Specifically, the connecting member 300 may include the first connection member 300a and the second connection member 300b positioned at two opposing sides of the connecting member 300 across the solder paste 150.

The first connection member 300a may be positioned closer to the portion of the solder paste 150 with the second height H2 than to the portion with the first height H1. The second connection member 300b may be positioned closer to the portion of the solder paste 150 with the first height H1 than to the portion with the second height H2.

The vertical distance from the top surface 210a of the base 210 of the light-emitting device 200 to the top of the first connecting member 300a may be a fourth height H4. The vertical distance from the top surface 210a of the base 210 of the light-emitting device 200 to the top of the second connecting member 300b may be a fifth height H5. The fourth height H4 may be greater than the fifth height H5. The difference between the fourth height H4 and the fifth height H5 may be less than or equal to 30 μm.

When the difference between the fourth height H4 and the fifth height H5 is greater than 30 μm, the strain generated in the second connecting member 300b may increase. As a result, the stress acting on the second connecting member 300b may increase. Therefore, when the difference between the fourth height H4 and the fifth height H5 is less than 30 μm, the stress acting on the second connecting member 300b may decrease. That is, the stress acting on the connecting member 300 may be reduced. As a result, the reliability of the electronic package device 12 may be improved.

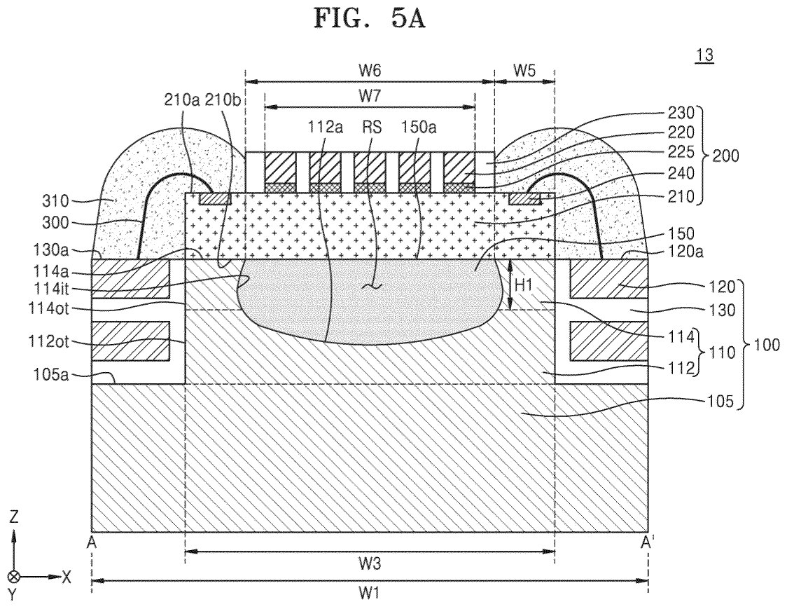

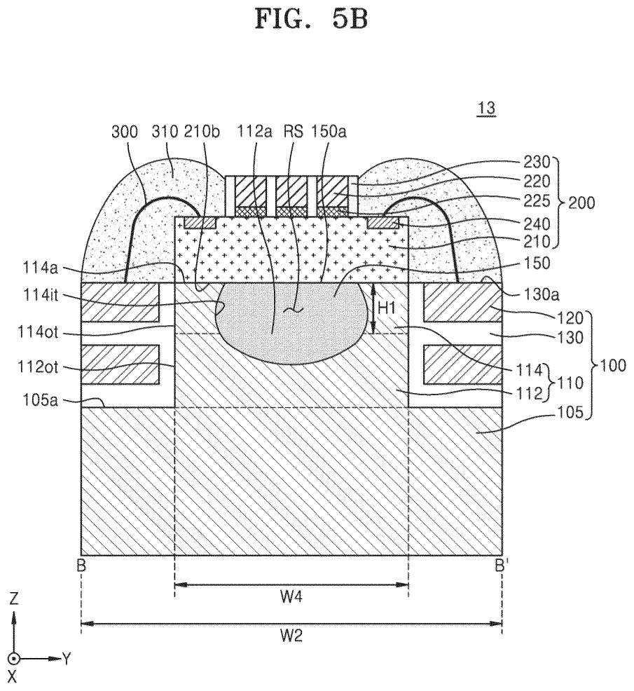

FIG. 5A is a cross-sectional view taken along line A-A′ in FIG. 1. FIG. 5B is a cross-sectional view taken along line B-B′ in FIG. 1. Hereinafter, descriptions that are substantially the same as those given with reference to FIGS. 1 to 2B are omitted to focus on differences.

Referring to FIGS. 1, 5A, and 5B, the surface of a recess RS formed in a second portion 114 of an electronic package device 13 may be rounded. Specifically, the inner wall 114it of the second portion 114 of the pad 110 and the top surface 112a of the first portion 112 may be rounded. The recess RS may be formed by wet etching.

Accordingly, the sixth width W6, which is the distance between the inner walls 114it of the pair of second portions 114 facing each other in the first horizontal direction (X), may increase and then decrease downward in the vertical direction (Z). In other words, the width of the solder paste 150 in the first horizontal direction (X) may increase and then decrease downward in the vertical direction (Z). The change in the width of the solder paste 150 in the first horizontal direction (X) may be due to the rounded surface of the recess RS.

The recess RS may also be formed in an upper part of the first portion 112. Alternatively, unlike in FIGS. 5A and 5B, the recess RS may be formed only in the second

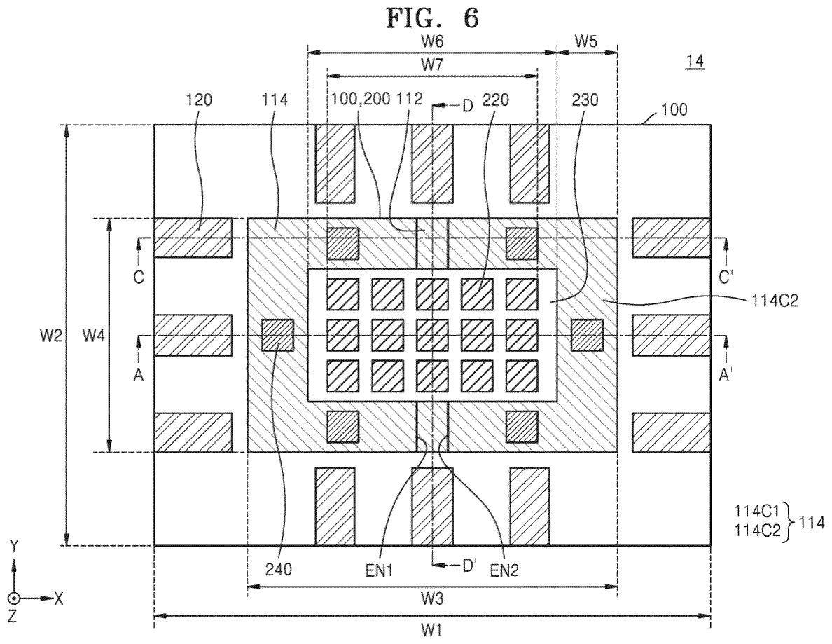

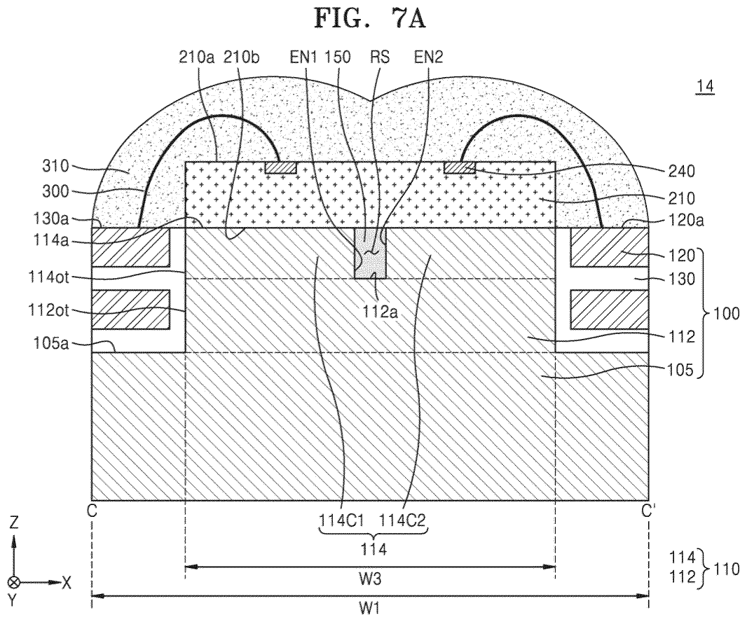

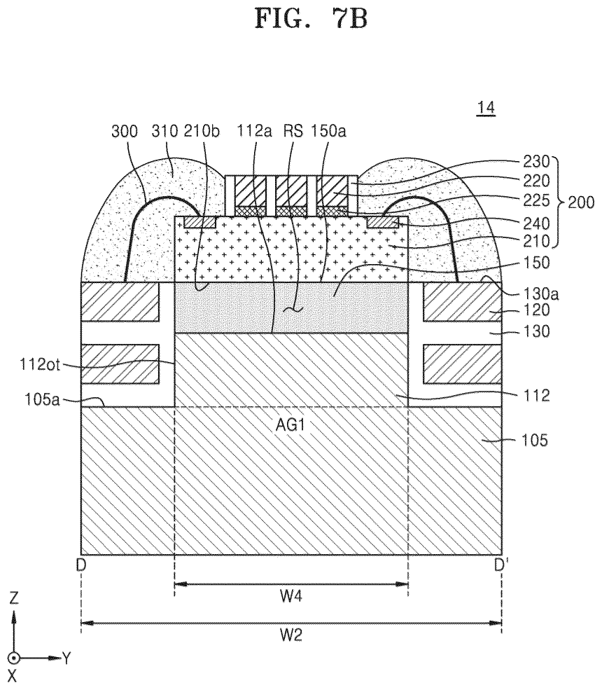

FIG. 6 is a plan view of an electronic package device according to an embodiment. FIG. 7A is a cross-sectional view taken along line C-C′ in FIG. 6. FIG. 7B is a cross-sectional view taken along line D-D′ in FIG. 6. Hereinafter, descriptions that are substantially the same as those given with reference to FIGS. 1 to 2B are omitted to highlight differences. The cross-sectional view taken along line A-A′ in FIG. 6 may correspond to FIG. 2A.

Referring to FIGS. 2A, 6, 7A, and 7B, a second portion 114 of an electronic package device 14 may include a first component 114C1 and a second component 114C2 spaced apart from each other in the first horizontal direction (X). In other words, the second portion 114 may be discontinuous in the first horizontal direction (X). The first component 114C1 and the second component 114C2 may be symmetrical to each other across a virtual plane with the first horizontal direction (X) as the normal line. Alternatively, the first component 114C1 and the second component 114C2 may be asymmetrical to each other across a virtual plane with the first horizontal direction (X) as the normal line.

The first component 114C1 may include a first end EN1. The second component 114C2 may include a second end EN2. The first end EN1 may be an inner wall of the first component 114C1 in the first horizontal direction (X). The second end EN2 may be an inner wall of the second component 114C2 in the first horizontal direction (X). The first end EN1 of the first component 114C1 may be spaced apart from the second end EN2 of the second component 114C2 in the first horizontal direction (X).

The recess RS may extend to a space formed by the first end EN1, the second end EN2, and the top surface 112a of the first portion 112. The solder paste 150 may extend to a space formed by the first end EN1, the second end EN2, and the top surface 112a of the first portion 112. As a result, the first component 114C1 may be spaced apart from the second component 114C2 in the first horizontal direction (X) with the solder paste 150 positioned in between.

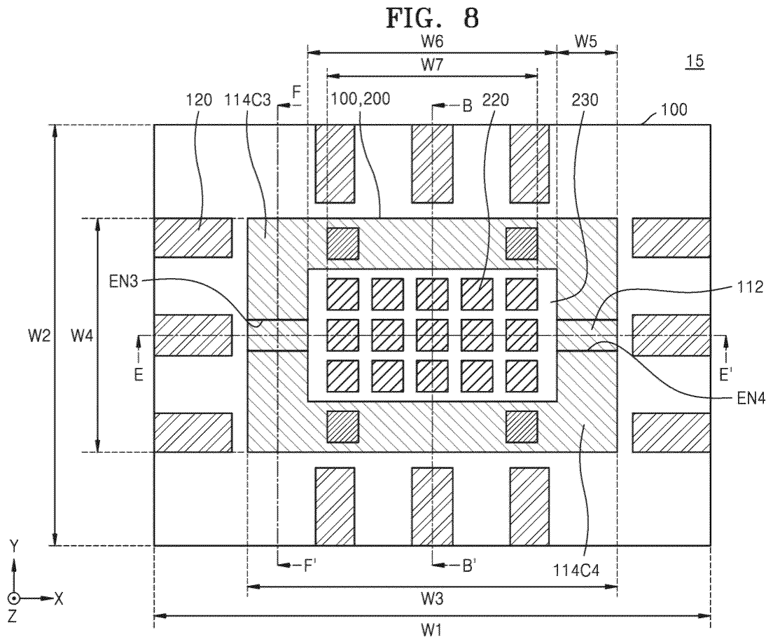

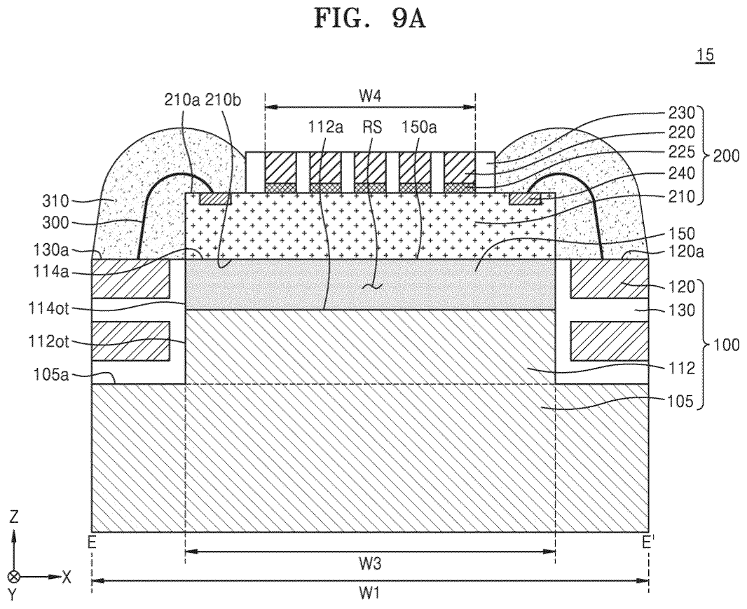

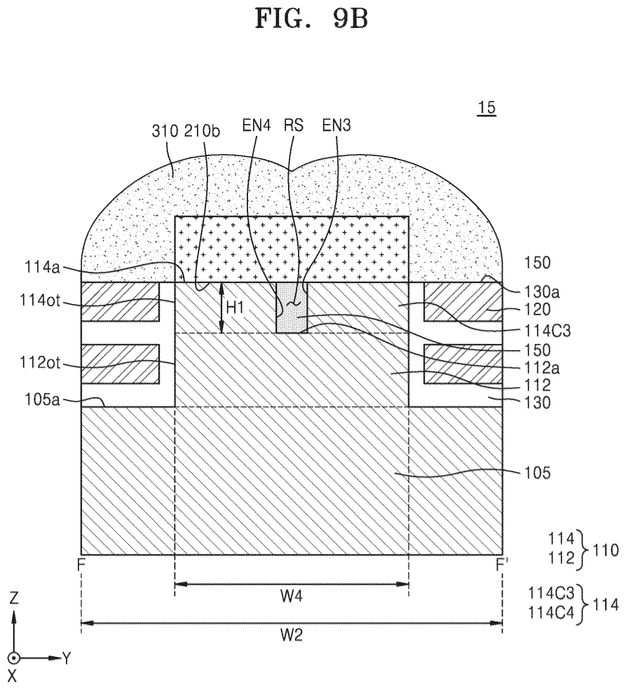

FIG. 8 is a plan view of an electronic package device according to an embodiment. FIG. 9A is a cross-sectional view taken along line E-E′ in FIG. 8. FIG. 9B is a cross-sectional view taken along line F-F′ in FIG. 8. Hereinafter, descriptions that are substantially the same as those given with reference to FIGS. 1 to 2B are omitted to highlight differences. The cross-sectional view taken along line B-B′ in FIG. 8 may correspond to FIG. 2B.

Referring to FIGS. 2B, 8, 9A, and 9B, a second portion 114 of an electronic package device 15 may include a third component 114C3 and a fourth component 114C4 spaced apart from each other in the second horizontal direction (Y). In other words, the second portion 114 may be discontinuous in the second horizontal direction (Y). The third component 114C3 and the fourth component 114C4 may be symmetrical to each other across a virtual plane with the second horizontal direction (Y) as the normal line. Alternatively, the third component 114C3 and the fourth component 114C4 may be asymmetrical to each other across a virtual plane with the second horizontal direction (Y) as the normal line.

The third component 114C3 may include a third end EN3. The fourth component 114C4 may include a fourth end EN4. The third end EN3 may be an inner wall of the third component 114C3 in the second horizontal direction (Y). The fourth end EN4 may be an inner wall of the fourth component 114C4 in the second horizontal direction (Y). The third end EN3 of the third component 114C3 may be spaced apart from the fourth end EN4 of the fourth component 114C4 in the second horizontal direction (Y).

The recess RS may extend to a space formed by the third end EN3, the fourth end EN4, and the top surface 112a of the first portion 112. The solder paste 150 may extend to a space formed by the third end EN3, the fourth end EN4, and the top surface 112a of the first portion 112. As a result, the third component 114C3 may be spaced apart from the fourth component 114C4 in the second horizontal direction (Y) with the solder paste 150 positioned therebetween.

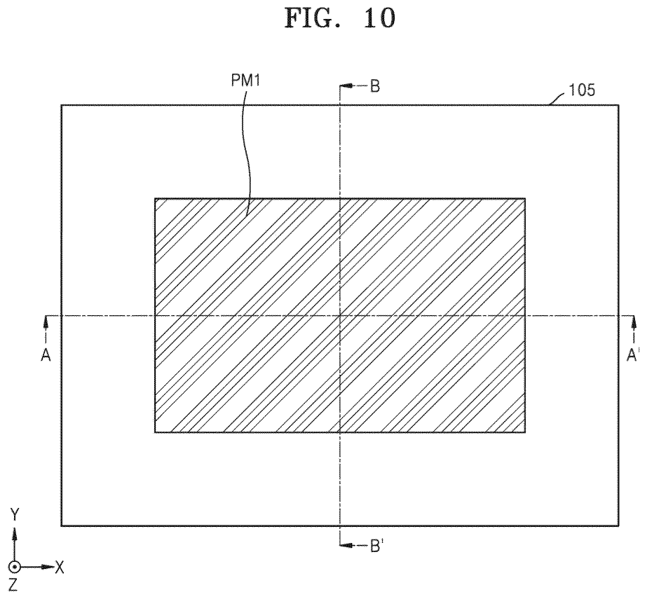

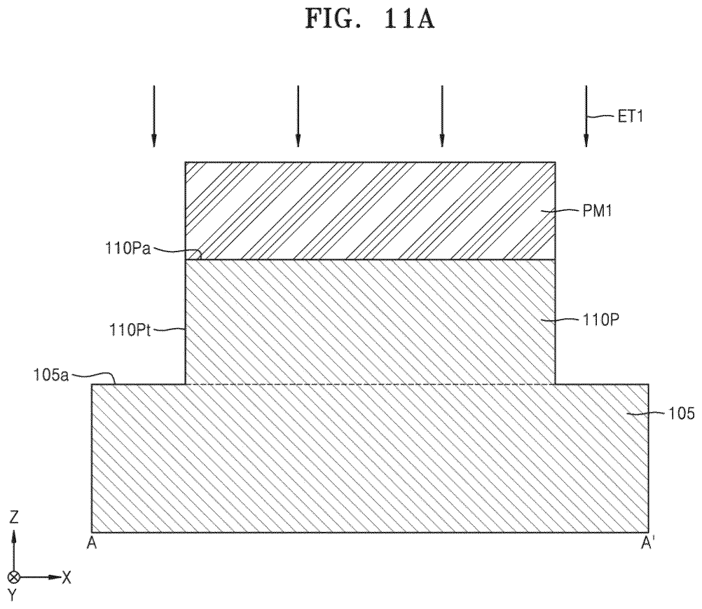

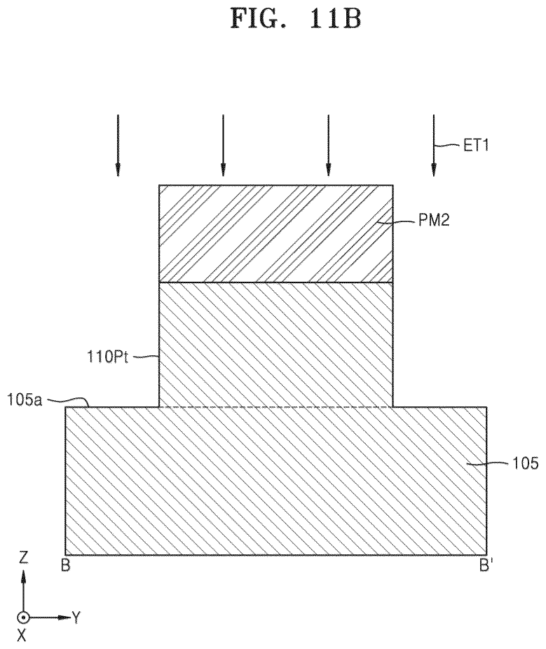

FIGS. 10, 12, 14, and 16 are plan views illustrating a method of manufacturing an electronic package device according to an embodiment. FIGS. 11A, 13A, 15A, and 17A are cross-sectional views, taken along line A-A′ in FIGS. 10, 12, 14, and 16, respectively, illustrating a method of manufacturing an electronic package device according to an embodiment. FIGS. 11B, 13B, 15B, and 17B are cross-sectional views, taken along line B-B′ in FIGS. 10, 12, 14, and 16, respectively, illustrating a method of manufacturing an electronic package device according to an embodiment.

Referring to FIGS. 10, 11A, and 11B, a flat plate 105 and a preliminary pad 110P on the flat plate 105 may be formed. Forming the flat plate 105 and the preliminary pad 110P on the flat plate 105 may include preparing a preliminary package substrate, forming a first photo mask pattern PM1 on the preliminary package substrate, and performing a first etching process ET1 on the preliminary package substrate using the first photo mask pattern PM1 as an etch mask.

The first photo mask pattern PM1 may cover a central portion of the preliminary package substrate. The first photo mask pattern PM1 may expose an edge of the preliminary package substrate. Accordingly, the edge of the preliminary package substrate may be etched through the first etching process ET1. The first etching process ET1 may lower the vertical level of the top surface of the edge of the preliminary package substrate, and may form the flat plate 105 and the preliminary pad 110P plate.

The vertical level of the top surface 105a of the flat plate 105 may be lower than the vertical level of a top surface 110Pa of the preliminary pad 110P.

The preliminary package substrate may be a PCB. Alternatively, the preliminary package substrate may be a copper substrate. Conductive wires may be positioned within the preliminary package substrate.

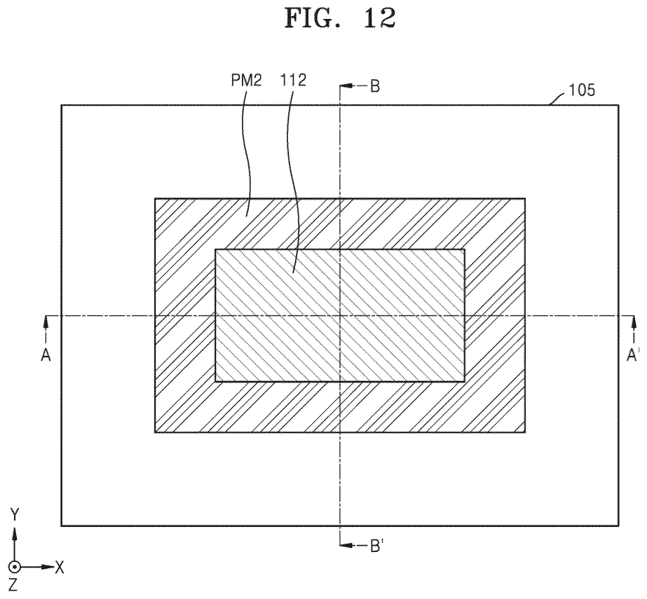

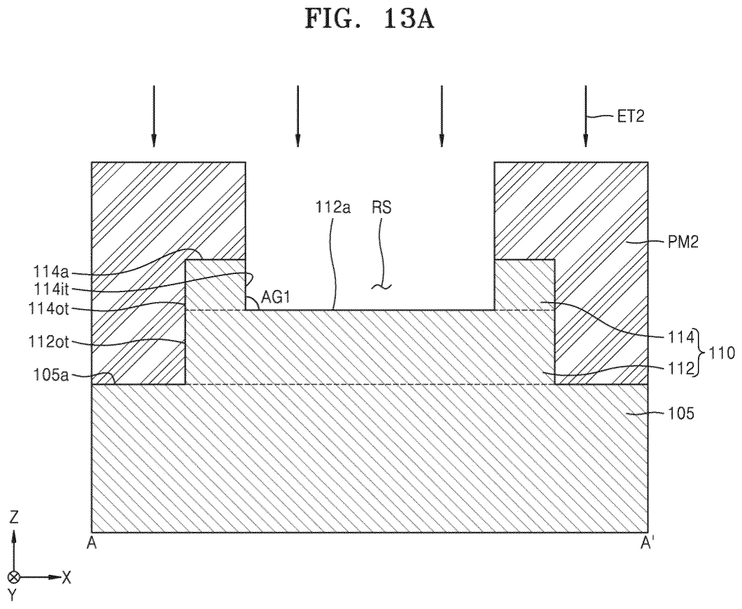

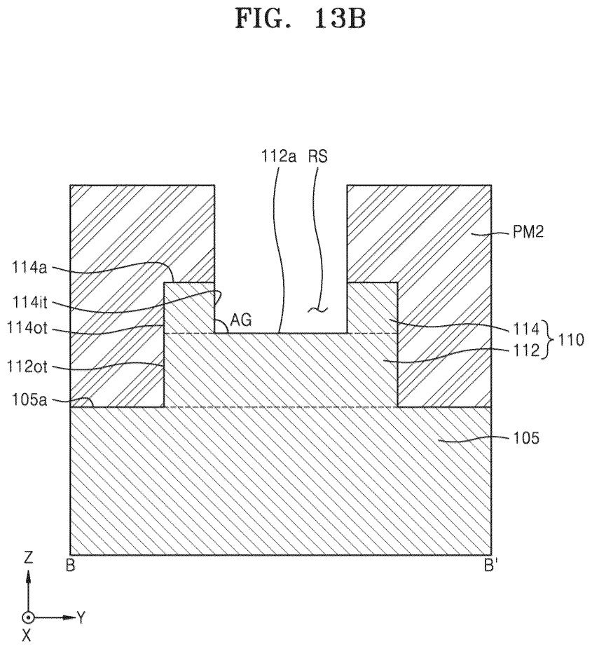

Referring to FIGS. 12, 13A, and 13B, the first photo mask pattern PM1 may be removed. Subsequently, the pad 110 may be formed from the preliminary pad 110P. Forming the pad 110 may include forming a second photo mask pattern PM2 on the flat plate 105 and the preliminary pad 110P and performing a second etching process ET2 on the preliminary pad 110P using the second photo mask pattern PM2 as an etch mask.

The second photo mask pattern PM2 may cover the top surface 105a of the flat plate 105 and the edge of the top surface of the preliminary pad 110P. The second photo mask pattern PM2 may expose a central portion of the preliminary pad 110P. Accordingly, the central portion of the preliminary pad 110P may be etched through the second etching process ET2. The second etching process ET2 may lower the vertical level of the top surface 110Pa of the central portion of the preliminary pad 110P. The second etching process ET2 may form the pad 110 from the preliminary pad 110P, and may form a recess RS in the central portion of the preliminary pad 110P.

The pad 110 may include a first portion 112 and a second portion 114 on the first portion 112. The recess RS may be a space defined by the top surface 112a of the first portion 112 and the inner walls 114it of the second portion 114.

An angle AG formed between the inner wall 114it of the second portion 114 and the top surface 112a of the first portion 112 may be a right angle or an obtuse angle. Specifically, the angle AG formed between the inner wall 114it of the second portion 114 and the top surface 112a of the first portion 112 may be about 90 degrees to about 145 degrees.

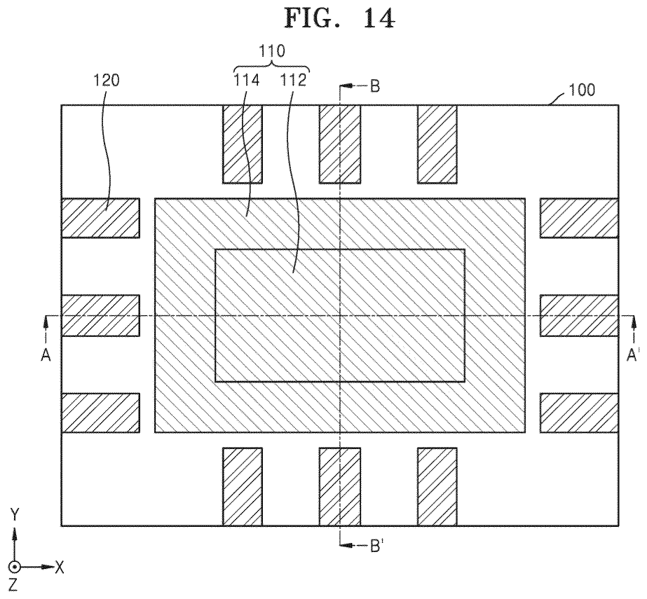

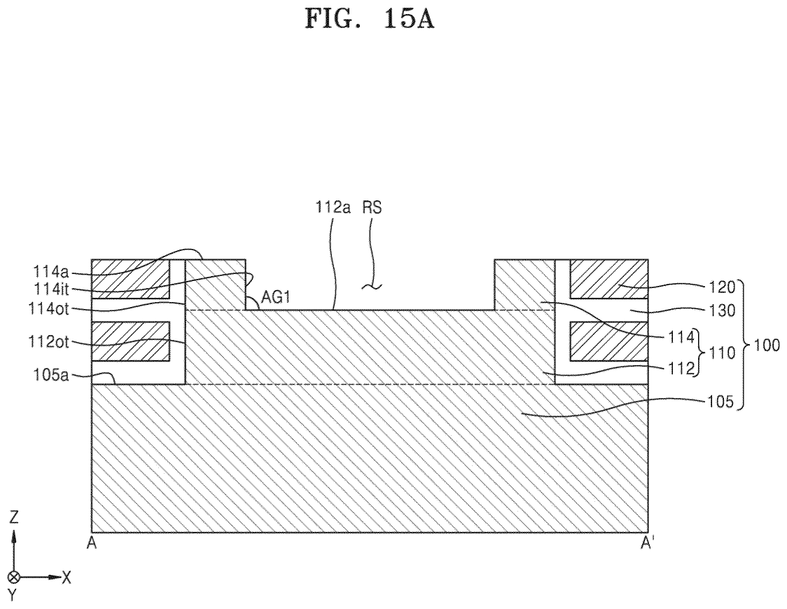

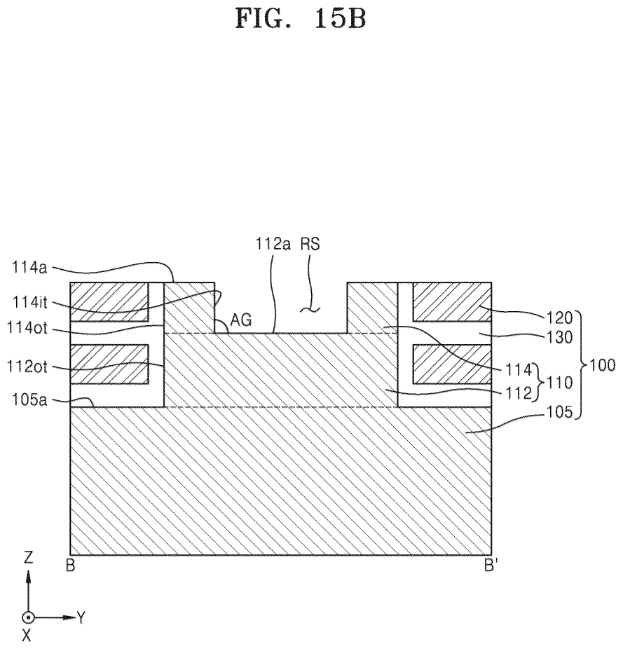

Referring to FIGS. 14, 15A, and 15B, the second photo mask pattern PM2 may be removed. Subsequently, the prepreg 130 and the connection wires 120 may be formed on the top surface 105a of the flat plate 105.

The prepreg 130 may include one layer or two or more layers. The connection wires 120 may be placed within the prepreg 130 and may include one or two or more layers.

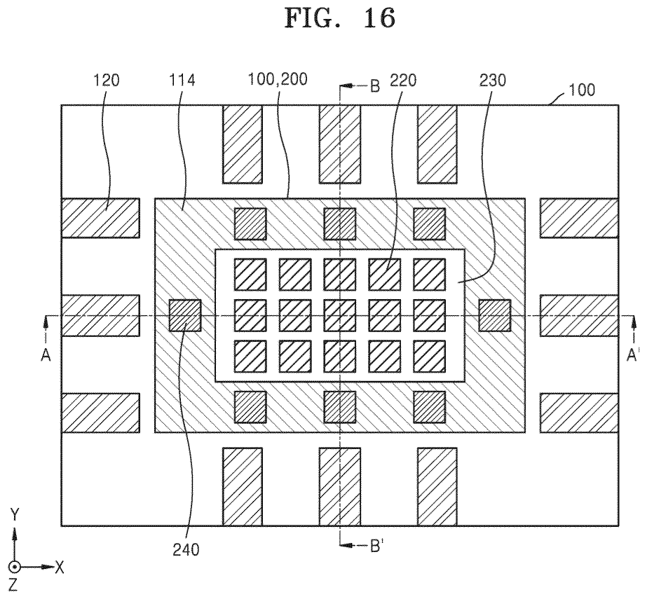

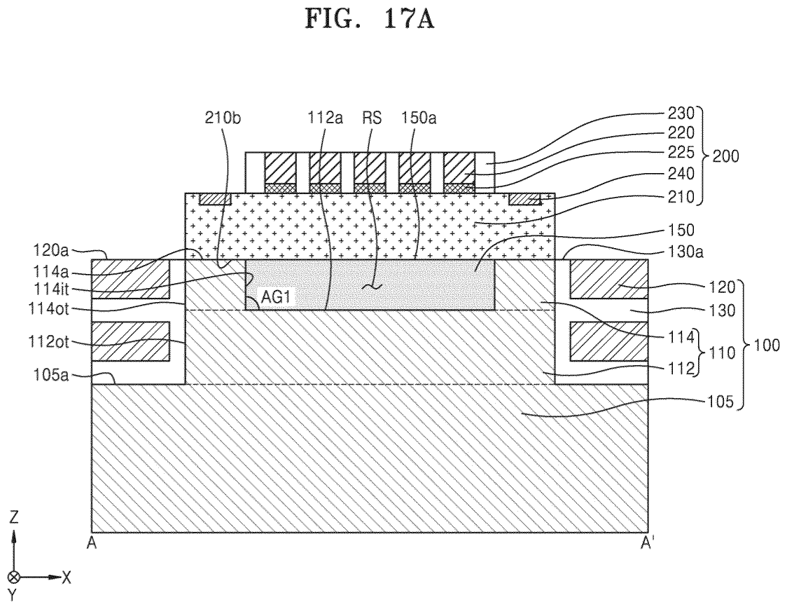

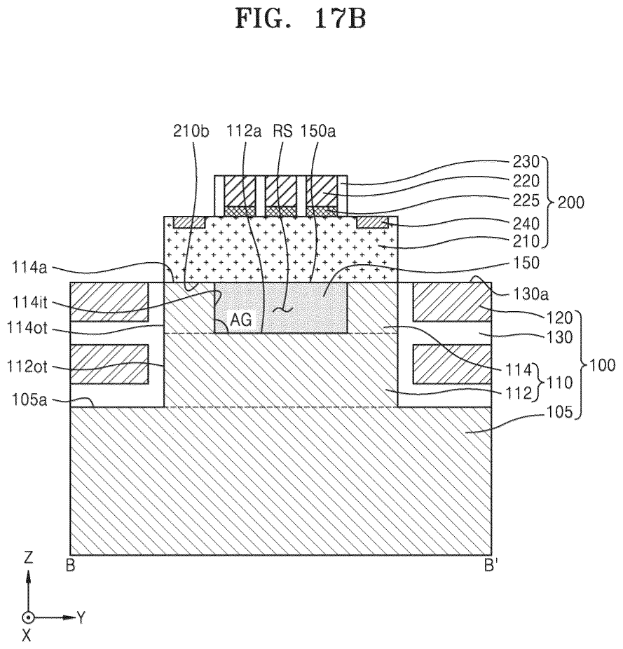

Referring to FIGS. 16, 17A, and 17B, the solder paste 150 may be formed to fill the recess RS. The solder paste 150 may cover the top surface 112a of the first portion 112 and the inner walls 114it of the second portion 114.

The light-emitting device 200 may be mounted on the top surface 114a of the second portion 114 and the top surface 150a of the solder paste 150. The light-emitting device 200 may include a base 210, a phosphor 220, a light-emitting diode 225, a grid 230, and an input/output pad 240. The light-emitting device 200 may be formed in another space.

A bottom surface 210b of the base 210 of the light-emitting device 200 may directly contact the top surface 114a of the second portion 114 and the top surface 150a of the solder paste 150.

Referring again to FIGS. 1, 2A, and 2B, the connecting member 300 may be formed to connect the input/output pad 240 of the light-emitting device 200 to the uppermost connection wire 120. Subsequently, the molding member 310 may be formed to cover the connecting member 300, the top surface 130a of the prepreg 130, and the top surface 120a of the uppermost connection wire 120. The molding member 310 may further cover the side surfaces and the top surface 210a of the base 210 and the side surfaces of the grid 230. As a result, the electronic package device 10 may be manufactured.

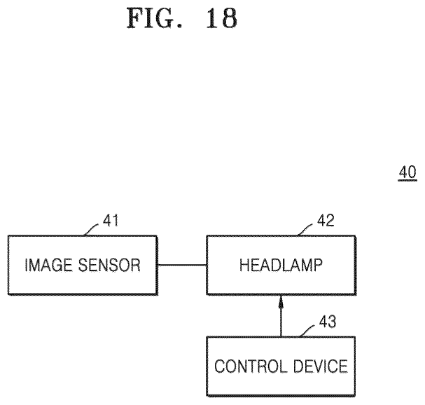

FIG. 18 is a block diagram of a headlamp control system.

Referring to FIG. 18, a headlamp control system 40 may include an image sensor 41, a headlamp 42, and a control device 43.

The image sensor 41 may include a camera and may obtain a front image by photographing the front of the vehicle. The image sensor 41 may transmit the obtained front image to the control device 43.

The headlamp 42 may radiate light to the front of the vehicle. The headlamp 42 may radiate light based on a radiation area set through the image sensor 41. The headlamp 42 may include an adaptive driving beam (ADB) system that changes the illumination angle, brightness, width, and length of the lamp. Alternatively, the headlamp 42 may include a high beam assistance (HBA) system that recognizes vehicles traveling in the opposite lane and automatically switches the high beam to the low beam.

The headlamp 42 may correspond to the electronic package devices 10, 11, 12, 13, 14, and 15 described with reference to FIGS. 1 to 9B.

The control device 43 may perform an illumination operation of the headlamp 42 based on the front image obtained from the image sensor 41. The control device 43 may be implemented as a processor and/or an electronic control unit (ECU), and may provide control commands to the headlamp 42.

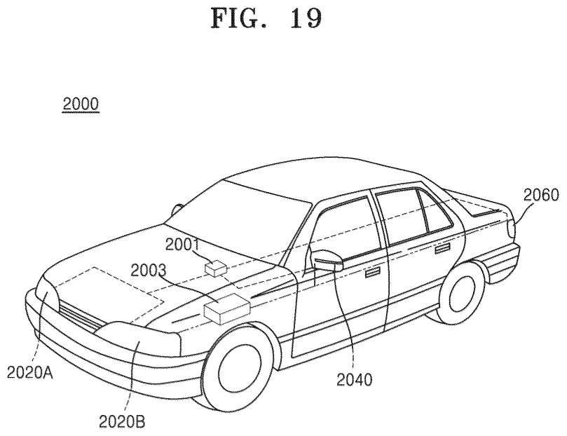

FIG. 19 is a diagram showing a vehicle including the headlamp control system of FIG. 18.

In FIG. 19, a car is shown as a vehicle 2000, but the inventive concept is not limited thereto. The vehicle 2000 may include a land transportation, such as two-wheeled vehicles, three-wheeled vehicles, passenger cars, crawler vehicles, trains, and trams, a marine transportation, such as ships, boats, and submarines, and an air transportation, such as airplanes and helicopters, but are specifically limited thereto.

Referring to FIG. 19, head lamps 2020A and 2020B of the vehicle 2000 may be installed, a side mirror lamp 2040 may be installed, and a tail lamp 2060 may be installed. At least one of the head lamps 2020A and 2020B, the side mirror lamp 2040, and the tail lamp 2060 may correspond to the electronic package devices 10, 11, 12, 13, 14, and 15 described with reference to FIGS. 1 to 9B.

A power device 2003 built into the vehicle 2000 may supply power to each of the head lamps 2020A and 2020B, the side mirror lamp 2040, and the tail lamp 2060. Additionally, a controller 2001 built into the vehicle 2000 may be configured to control operations including on and off of the head lamps 2020A and 2020B, the side mirror lamp 2040, and the tail lamp 2060. The controller 2001 may correspond to the control device 43 shown in FIG. 18.

The foregoing exemplary embodiments are merely exemplary and are not to be construed as limiting. The present teaching can be readily applied to other types of apparatuses. Also, the description of the exemplary embodiments is intended to be illustrative, and not to limit the scope of the claims, and many alternatives, modifications, and variations will be apparent to those skilled in the art.

What is claimed is:

1. An electronic package device comprising:
a package substrate comprising a flat plate and a pad on the flat plate, wherein a width of the flat plate in a first horizontal direction is greater than a width of the pad in the first horizontal direction; and
a light-emitting device on the package substrate,
wherein the pad comprises:
a first portion; and
a second portion positioned on a top surface of the first portion and positioned at an edge of the top surface of the first portion, and
a width of the light-emitting device in the first horizontal direction is substantially equal to a width of the pad in the first horizontal direction.

2. The electronic package device of claim 1, further comprising solder paste filling a space surrounded by the top surface of the first portion and inner walls of the second portion.

3. The electronic package device of claim 2, wherein a vertical level of a top surface of the solder paste is substantially equal to a vertical level of a top surface of the second portion.

4. The electronic package device of claim 1, wherein the second portion has a ring shape or an annular shape from a plan view.

5. The electronic package device of claim 1, wherein a top surface of the second portion is in direct contact with a bottom surface of the light-emitting device.

6. The electronic package device of claim 1, wherein a width of the light-emitting device in the first horizontal direction is greater than a width of the light-emitting device in a second horizontal direction intersecting the first horizontal direction, and the width of the light-emitting device in the second horizontal direction is in a range from 2 mm to 6 mm.

7. The electronic package device of claim 1, wherein the light-emitting device comprises:
a base;
a plurality of phosphors disposed on the base and spaced apart from each other in the first horizontal direction; and
a grid surrounding sidewalls of the plurality of phosphors.

8. The electronic package device of claim 1, wherein a vertical height of the second portion is in a range from 10 μm to 500 μm.

9. The electronic package device of claim 1, wherein the width of the pad in the first horizontal direction is a first width,
the width of the pad in a second horizontal direction intersecting the first horizontal direction is a second width,
a minimum distance from an outer wall to an inner wall of the second portion is a third width,
the second width is less than the first width,
the third width is less than half of the second width, and
the third width is greater than to or equal to 50 μm.

10. The electronic package device of claim 1, further comprising solder paste filling a space surrounded by the top surface of the first portion and inner walls of the second portion,
wherein a vertical level of a top surface of the solder paste is higher than a vertical level of a top surface of the second portion,
the top surface of the solder paste is inclined in the first horizontal direction, a minimum distance from the top surface of the second portion to the top surface of the solder paste is a first height,
a maximum distance from the top surface of the second portion to the top surface of the solder paste is a second height, and
a difference between the first height and the second height is less than or equal to 30 μm.

11. The electronic package device of claim 10, wherein the light-emitting device comprises a base and input/output pads disposed on an upper part of the base,
the electronic package device further comprises connection wires disposed on a top surface of the flat plate of the package substrate,
the electronic package device further comprises a first connecting member that directly connects one of the connection wires to one of the input/output pads,
the electronic package device further comprises a second connecting member that directly connects another one of the connection wires to another one of the input/output pads,
a vertical distance from a top surface of the base to the top of the first connecting member is a third height,
a vertical distance from the top surface of the base to the top of the second connecting member is a fourth height, and
a difference between the third height and the fourth height is less than or equal to 30 μm.

12. An electronic package device comprising:
a package substrate comprising a flat plate and a pad on the flat plate, wherein a width of the flat plate in a first horizontal direction is greater than a width of the pad in the first horizontal direction;
a light-emitting device on the package substrate, wherein the light-emitting device comprises a base, a plurality of phosphors disposed on the base and spaced apart from each other in the first horizontal direction, and a grid surrounding sidewalls of the plurality of phosphors; and
solder paste positioned between the light-emitting device and the pad,
wherein the pad comprises:
a first portion; and
a second portion disposed on a top surface of the first portion and arranged in a ring shape or an annular shape along an edge of the top surface of the first portion,
the solder paste fills a space defined by the top surface of the first portion and inner walls of the second portion, and
the plurality of phosphors are included in the solder paste from a plan view.

13. The electronic package device of claim 12, further comprising a plurality of light-emitting diodes positioned between each of the plurality of phosphors and the base.

14. The electronic package device of claim 12, wherein a vertical level of a top surface of the solder paste is substantially equal to a vertical level of a top surface of the second portion.

15. The electronic package device of claim 12, wherein a vertical height of the second portion is in a range from 10 μm to 500 μm.

16. The electronic package device of claim 12, wherein the width of the pad in the first horizontal direction is a first width,
the width of the pad in a second horizontal direction intersecting the first horizontal direction is a second width,
a minimum distance from an outer wall to an inner wall of the second portion is a third width,
the second width is less than the first width,
the third width is less than half of the second width, and
the third width is greater than or equal to 50 μm.

17. The electronic package device of claim 12, wherein a vertical level of a top surface of the solder paste is higher than a vertical level of a top surface of the second portion,
the top surface of the solder paste is inclined in the first horizontal direction,
a minimum distance from the top surface of the second portion to the top surface of the solder paste is a first height,
a maximum distance from the top surface of the second portion to the top surface of the solder paste is a second height, and
a difference between the first height and the second height is less than or equal to 30 μm.

18. The electronic package device of claim 17, wherein the light-emitting device further comprises input/output pads disposed on an upper part of the base,
the electronic package device further comprises:
connection wires disposed on a top surface of the flat plate of the package substrate,
a first connecting member that directly connects one of the connection wires to one of the input/output pads,
a second connecting member that directly connects another one of the connection wires to another one of the input/output pads,
a vertical distance from the top surface of the base to the top of the first connecting member is a third height,
a vertical distance from the top surface of the base to the top of the second connecting member is a fourth height, and
a difference between the third height and the fourth height is less than or equal to 30 μm.

19. An electronic package device comprising:
a package substrate comprising a flat plate and a pad on the flat plate, wherein a width of the flat plate in a first horizontal direction is greater than a width of the pad in the first horizontal direction;
a light-emitting device on the package substrate, wherein the light-emitting device comprises a base, a plurality of phosphors disposed on the base and spaced apart from each other in the first horizontal direction, a grid surrounding sidewalls of the plurality of phosphors, and an input/output pad disposed on an upper part of the base;
solder paste positioned between the light-emitting device and the pad;
prepreg on a top surface of the flat plate, wherein the prepreg surrounds sides of the pad;
a connection wire disposed within the prepreg;
a connecting member that directly connects the connection wire to the input/output pad; and
a molding member covering the connecting member,
wherein the pad comprise:
a first portion; and
a second portion positioned on a top surface of the first portion and positioned at an edge of the top surface of the first portion,
the solder paste fills a space defined by the top surface of the first portion and inner walls of the second portion, and
a top surface of the second portion is in direct contact with a bottom surface of the light-emitting device.

20. The electronic package device of claim 19, wherein a vertical level of a top surface of the solder paste is substantially equal to a vertical level of a top surface of the second portion.
